(19) United States
(12) Patent Application Publication
(10) Pub. No.: US 2026/0190730 A1
(43) Pub. Date: Jul. 2, 2026

(54) Display Apparatus

(71) Applicant: LG Display Co., Ltd., Seoul (KR)

(72) Inventors: Jung-Seop Yoon, Paju-si (KR); Hyun-Jik Bae, Paju-si (KR); Byung-June Mun, Paju-si (KR)

(21) Appl. No.: 19/345,299

(22) Filed: Sep. 30, 2025

(30) Foreign Application Priority Data
Dec. 30, 2024 (KR) 10-2024-0200244

(51) Int. Cl. H10K 59/35; H10H 29/30; H10H 29/32; H10H 29/34; H10H 29/49; H10H 29/853; H10H 29/855; H10K 59/121; H10K 59/131; H10K 59/40; H10K 59/65; H10K 59/80

(52) U.S. Cl. CPC H10K 59/352; H10H 29/32; H10H 29/345; H10H 29/352; H10H 29/49; H10H 29/853; H10H 29/8552; H10K 59/1213; H10K 59/131; H10K 59/353; H10K 59/40; H10K 59/65; H10K 59/873; H10K 59/8792

(57) ABSTRACT

A display apparatus comprises a display panel comprising a display area and a sensor area within the display area, the sensor area comprising a sensor display area to display an image and a sensor transparent area to transmit light, and a sensor module disposed on a lower surface of the display panel to be aligned with the sensor area. A first sensor sub-pixel, a second sensor sub-pixel and a third sensor sub-pixel displaying different colors are arranged in the sensor display area and a plurality of second sensor sub-pixels and a plurality of third sensor sub-pixels are arranged in the sensor display area.

### CROSS-REFERENCE TO RELATED APPLICATIONS

This application claims priority under 35 U.S.C. § 119(a) to the Republic of Korea Patent Application No. 10-2024-0200244, filed in the Republic of Korea on Dec. 30, 2024, the entire contents of which are hereby expressly incorporated by reference into the present application.

### TECHNICAL FIELD

The present disclosure relates to a display device, and more particularly, to a camera-embedded display apparatus with beneficial lifespan.

### BACKGROUND

As information technologies developed, various small and thin types of display devices such as a liquid crystal display device, an organic light emitting display device, a plasma device and a micro LED display device have been developed.

Such display devices are embedded with a camera to provide users with various functions. In the camera-embedded display device, a camera hole for placing the camera is formed. In this case images are not displayed in the area where the camera hole is disposed, thus, there was a problem that the image displayed on the display device was disconnected, and that the disconnected image was perceived by user.

### SUMMARY

Accordingly, some embodiments of the present disclosure are directed to a display apparatus that substantially obviates one or more of the problems due to the limitations and disadvantages of the related art.

An aspect of the present disclosure is to provide a display apparatus in which an image of an area in which a sensor is embedded within a display area is not interrupted or disconnected.

Another aspect of the present disclosure is to provide a display apparatus capable of preventing shortening of lifespan due to excessive current by maximizing a light-emitting area of the area in which the sensor is embedded.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, the present disclosure provides a display apparatus comprising a display panel comprising a display area and a sensor area within the display area, the sensor area comprising a sensor display area for displaying an image and a sensor transparent area for transmitting light; a sensor module disposed on a lower surface of the display panel and aligned with the sensor area; and a sensor display area pixel comprising a first sensor sub-pixel, a plurality of second sensor sub-pixels and a plurality of third sensor sub-pixels arranged in the sensor display area, wherein the first sensor sub-pixel is configured to display a first color, the plurality of second sensor sub-pixels is configured to display a second color, and the plurality of third sensor sub-pixels is configured to display a third color. The plurality of second sensor sub-pixels and the plurality of third sensor sub-pixels are arranged around the first sensor sub-pixel.

The first sensor sub-pixel, the second sensor sub-pixel and the third sensor sub-pixel can display one color among red, green and blue, respectively.

In one embodiment, the first sensor sub-pixel can be arranged in a central region of the sensor display area.

The first sensor sub-pixel can be extended to a boundary area between the sensor display area and the sensor transparent area.

The first sensor sub-pixel can be extended to the sensor transparent area from the sensor display area.

The second sensor sub-pixels and the third sensor sub-pixels can be arranged around the first sensor sub-pixel.

The second sensor sub-pixels and the third sensor sub-pixels can be extended to the sensor transparent area from the sensor display area.

The display apparatus can further comprise a first thin film transistor disposed in the first sensor sub-pixel; a second thin film transistor disposed in the second sensor sub-pixels; a third thin film transistor disposed in the third sensor sub-pixels; a first light-emitting diode disposed in the first sensor sub-pixel; a plurality of second light-emitting diodes disposed in each of the second sensor sub-pixels, respectively; and a plurality of third light-emitting diode disposed in each of the third sensor sub-pixels, respectively.

Emission layers of the plurality of the second light-emitting diodes can be integral.

In one embodiment, the plurality of second light-emitting diodes can be electrically connected to the second thin film transistor and the plurality of third light-emitting diodes can be electrically connected to the third thin film transistor.

Each of the first thin film transistor, the second thin film transistor and the third thin film transistor comprises a semiconductor layer; a gate insulating layer disposed on the semiconductor layer; a gate electrode disposed on the gate insulating layer; an interlayer insulating layer disposed on the gate electrode; and a source electrode and a drain electrode disposed on the interlayer insulating layer.

The second sensor sub-pixel can comprise a second-first sensor sub-pixel and at least one second-second sensor sub-pixel, and the third sensor sub-pixel can comprise a third-first sensor sub-pixel and at least one third-second sensor sub-pixel.

In another embodiment, the display apparatus can further comprises a first connecting electrode disposed on the interlayer insulating layer of the at least one second-second sensor sub-pixel; and a second connecting electrode disposed on the interlayer insulating layer of the at least one third-second sensor sub-pixel.

For example, the first connecting electrode can comprise a same material as the drain electrode of the second thin film transistor and the second connecting electrode can comprise a same material as the drain electrode of the third thin film transistor.

The second thin film transistor can be directly connected to the second light-emitting diode disposed in the second-first sensor sub-pixel and can be connected to the second light-emitting diode disposed in the second-second sensor sub-pixel through the first connecting electrode.

The third thin film transistor can be directly connected to the third light-emitting diode disposed in the third-first sensor sub-pixel and can be connected to the third light-emitting diode disposed in the third-second sensor sub-pixel through the second connecting electrode.

For example, the display area can comprise a first sub-pixel, a second sub-pixel and a third sub-pixel.

The first sensor sub-pixel can have an area larger than an area of the first sub-pixel.

The second sensor sub-pixel can have an area that is substantially a same as an area of the second sub-pixel.

The third sensor sub-pixel can have an area that is substantially a same as an area of the third sub-pixel.

The first sensor sub-pixel may comprise a single emissive layer only.

The first sensor sub-pixel may be directly surrounded by a plurality of sensor transparent areas.

The first sensor sub-pixel may be directly adjacent to at least four sensor transparent areas.

The second sensor sub-pixels and the third sensor sub-pixels may be directly adjacent to the first sensor sub-pixel.

A size of a sensor display area pixel may be greater than a size of a display area pixel.

One sensor area may comprise at least four sensor transparent areas.

In one or more embodiments, the sensor area comprises the sensor display area where the image is displayed and the sensor transparent area so that the sensor area can display the image and detect external light simultaneously. Therefore, compared to a conventional configuration in which a sensor is placed in a notch or a configuration in which a hole is formed in the display area, it is possible to prevent a reduction in the area of the display area or an image from being disconnected or interrupted.

Also, plural sensor sub-pixels are arranged in one sensor display area in the display apparatus, and thereby increasing the light-emitting area emitting light in the sensor area. Therefore, as the light-emitting area increases, the difference in brightness between the display area and the sensor area can be minimized even if the amount of current applied to the sensor sub-pixels is not increased, so that the shortening of the lifespan of the display apparatus can be prevented.

In addition, since the amount of current applied to the sensor sub-pixels can be reduced in the display apparatus, a low-power display apparatus capable of reducing power consumption can be implemented.

It is to be understood that both the foregoing general description and the following detailed description are exemplary and explanatory, and are intended to provide further explanation of the inventive concepts as claimed.

### BRIEF DESCRIPTION OF THE DRAWINGS

The accompanying drawings, which provide a further understanding of the disclosure, are incorporated in and constitute a part of this application, illustrate embodiments of the disclosure and together with the description serve to explain principles of the disclosure.

FIG. 1 illustrates a schematic block diagram of a display apparatus in accordance with the present disclosure.

FIG. 2 illustrates a schematic block diagram of a sub-pixel in the display apparatus in accordance with the present disclosure.

FIG. 3 illustrates a schematic circuit diagram of a sub-pixel in the display apparatus in accordance with the present disclosure.

FIG. 4 illustrates an exploded perspective view of the display apparatus in accordance with an embodiment of the present disclosure.

FIG. 5 illustrates a plane view of a display panel of the display apparatus in accordance with an embodiment of the present disclosure.

FIG. 6 illustrates a plane view enlarging an area “A” in FIG. 5.

FIG. 7 illustrates a schematic plane view of sensor sub-pixels of the display apparatus in accordance with an embodiment of the present disclosure.

FIG. 8A illustrates a cross-sectional view taken along a line I-I′ in FIG. 7.

FIG. 8B illustrates a cross-sectional view taken along a line II-II′ in FIG. 7.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing embodiments of the present disclosure are merely illustrative examples, and thus the present disclosure is not limited to the illustrated examples. The same reference numerals refer to the same components throughout this disclosure unless otherwise specified. Further, in the following description of the present disclosure, where a detailed description of a known related art may unnecessarily obscure the gist of the present disclosure, the detailed description thereof may be omitted herein or may be briefly discussed.

Where terms such as “including,” “having,” “comprising,” and the like are used in this disclosure, other parts can be added unless a more limiting term like “only” is used herein. Further, where a component is expressed as being singular, being plural is included, and vice versa, unless otherwise specified.

In analyzing a component, an error range should be interpreted as being included even where there is no explicit description.

In describing a positional relationship, for example, where a positional relationship of two parts/layers is described as being “over,” “on,” “above,” “below,” “under,” “next to,” or the like, one or more other parts/layers can be provided between the two parts/layers, unless a more limiting term like “immediately” or “directly” is used therewith.

In describing a temporal relationship, for example, where a temporal predecessor relationship is described as being “after,” “subsequent,” “next to,” “prior to,” or the like, unless a more limiting term like “immediately” or “directly” is used, cases that are not continuous or sequential can also be included

Although the terms first, second, and the like may be used to describe various components, these components are not substantially limited by these terms. These terms are used only to refer to one component separately from another component, and may not define any particular order or sequence. Therefore, a first component described below can substantially be a second component, and vice versa.

In describing components of the present disclosure, terms such as first, second, A, B, (a), (b), etc. may be used. These terms are only intended to distinguish the components from other components, and the nature, order, sequence, or numbers of the components are not limited by the terms. When it is described that a component is “joined”, “coupled” or “connected” to another component, it should be understood that the component may be directly connected or connected to the other component, but that other components may also be “interposed” between each component, or that each component may be “connected,” “coupled,” or “connected” through another component.

Features of various embodiments of the present disclosure can be partially or entirely united or combined with each other, technically various interlocking and driving are possible, and each of the embodiments can be independently implemented with respect to each other or implemented together in a co-dependent relationship.

All the components of each display apparatus according to all embodiments of the present disclosure are operatively coupled and configured.

As used herein, ‘display apparatus’or ‘display device” can comprise a narrowly defined display apparatus such as a display module including a display panel and a driving unit for driving the display panel. In addition, the display apparatus can also include a set electronic device or a set apparatus such as a notebook computer, a television, a computer monitor, an automotive display, or other forms of a vehicle, which are complete products (or final products) including a display module, an equipment display, a mobile electronic device such as a smart phone or an electronic pad, and the like.

Therefore, the display apparatus in the present disclosure can include a narrowly defined display apparatus itself such as a display module, and a set apparatus which is an application product or a final consumer device including a display module.

Reference will now be made in detail to aspects of the disclosure, examples of which are illustrated in the accompanying drawings. Wherever possible, the same reference numbers will be used throughout the drawings to refer to the same or like parts.

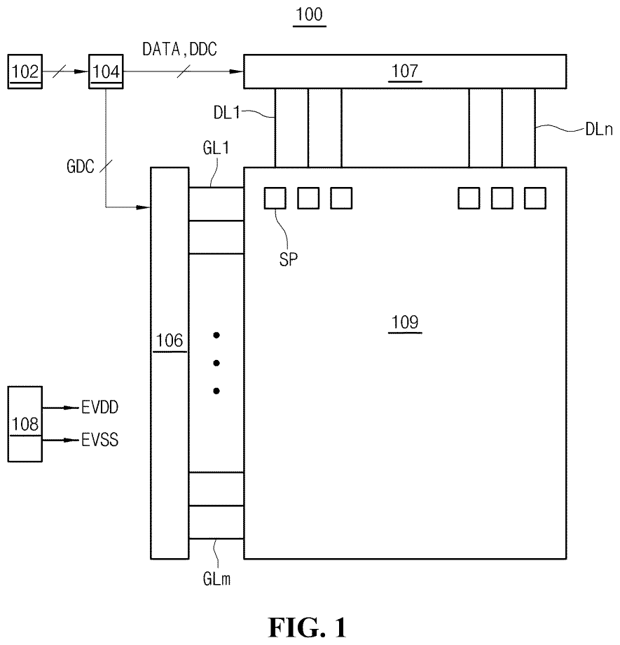

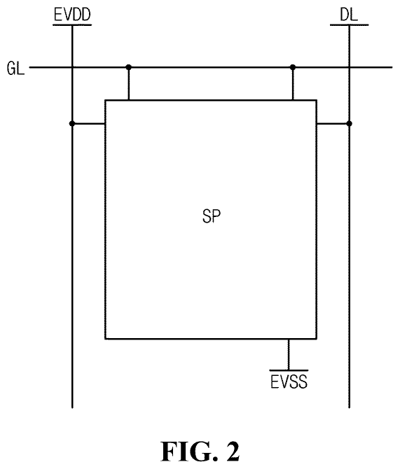

FIG. 1 illustrates a schematic block diagram of a display apparatus in accordance with the present disclosure. FIG. 2 illustrates a schematic block diagram of a sub-pixel in the display apparatus in accordance with the present disclosure.

As illustrated in FIG. 1, a display apparatus 100 can comprise an image processor 102, a timing controller 104, a gate driver 106, a data driver 107, a power supplier 108 and a display panel 109.

The image processor 102 outputs driving signals for driving various components together with an image data supplied from outside. For example, the driving signal output form the image processor 102 can comprise, but is not limited to, a data enable signal, a vertical synchronization signal, a horizontal synchronization signal, a clock signal, and the like.

The timing controller 104 receives driving signals along with an image data from the image processor 102. The timing controller 104 generates and outputs a gate timing control signal GDC for controlling an operation timing of the gate driver 106 and a data timing control signal DDC for controlling an operation timing of the data driver 107 based on the driving signal input from the image processor 102.

The gate driver 106 outputs a scan signal to the display panel 109 in response of the gate timing control signal GDC supplied from the timing controller 104. The gate driver 106 outputs the scan signal though a plurality of gate lines GL1 to GLm (m is an integer equal to or greater than 2). In one embodiment, the gate driver 106 can be shaped as an integrated circuit (IC), but is not limited thereto.

The data driver 107 outputs data voltage to the display panel 109 in response of the data timing control signal DDC input from the timing controller 104. The data driver 107 samples and latches a digital-type data signal DATA supplied from the timing controller 104 and convers the digital-type data signal DATA into analog-type data voltage based on a gamma voltage. The data driver 107 outputs the data voltage through a plurality of data lines DL1 to DLn (n is an integer equal to or greater than 2). In one embodiment, the data driver 107 can be shaped as an integrated circuit (IC), but is not limited thereto.

The power supplier 108 outputs high-potential voltage VDD and low-potential voltage VSS and supplies the voltages VDD and VSS to the display panel 109. The high-potential voltage VDD is supplied to the display panel 109 through a first power line EVDD and the low-potential voltage VSS is supplied to the display panel 109 through a second power line EVSS. Alternatively or additionally, the voltages output from the power supplier 108 can be output to the gate driver 106 and/or the data driver 107 for driving those drivers 106 and 107.

The display panel 109 display images in response to the scan signal supplied from the gate driver 106, the data voltage supplied from the data driver 107 and the power supplied from the power supplier 108.

The display panel 109 comprises a plurality of sub-pixels SPs to display an image. In one embodiment, the sub-pixel SP can comprise a red (R) sub-pixel, a green (G) sub-pixel and a blue (B) sub-pixel. Alternatively, the sub-pixel SP can comprise a white (W) sub-pixel, a red (R) sub-pixel, a green (G) sub-pixel and a blue (B) sub-pixel. In one embodiment, the white (W), red (R), green (G) and blue (B) sub-pixels can have a substantially same area. Alternatively, the white (W), red (R), green (G) and blue (B) sub-pixels can have different areas.

As illustrated in FIG. 2, each sup-pixel SP can be connected to a gate line GL, a data line DL, a first power line EVDD and a second power line EVSS. The numbers and driving methods of a transistor and a capacitor can be determined by configuration of the pixel circuit in the sub-pixel SP.

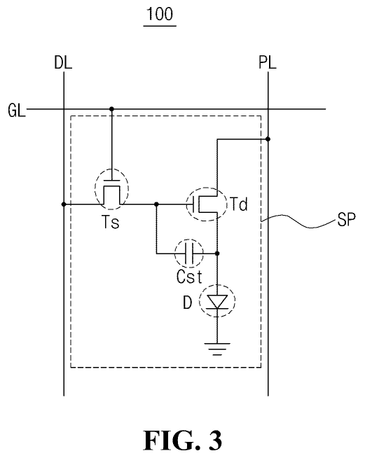

FIG. 3 illustrates a schematic circuit diagram of a sub-pixel in the display apparatus in accordance with the present disclosure.

As illustrated in FIG. 3, the display apparatus 100 includes a gate line GL, a data line DL and a power line PL crossing each other to define the sub-pixel SP. A switching thin film transistor Ts, a driving thin film transistor Td, a storage capacitor Cst and a light-emitting diode D can be disposed in the sub-pixel SP.

The switching thin film transistor Ts is connected to the gate line GL and the data line DL. The driving thin film transistor Td and the storage capacitor Cst are connected between the switching thin film transistor Ts and the power line PL, and the light-emitting diode D is connected to the driving thin film transistor Td.

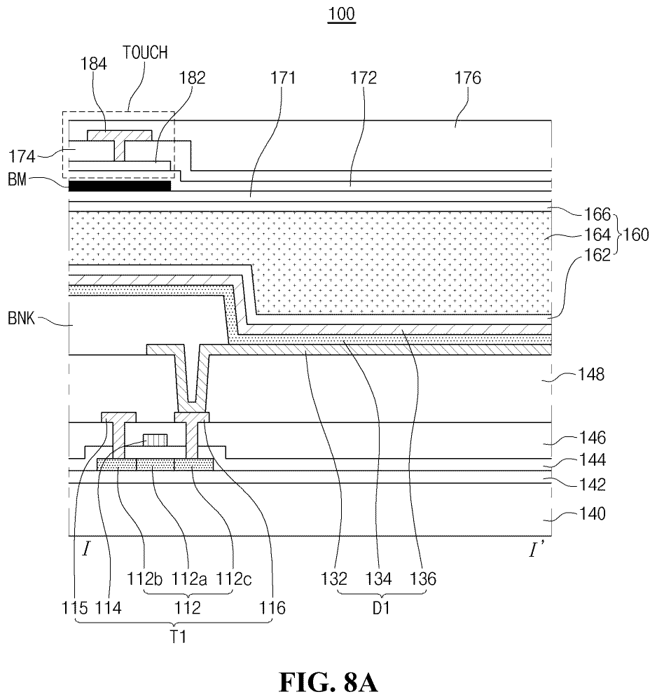

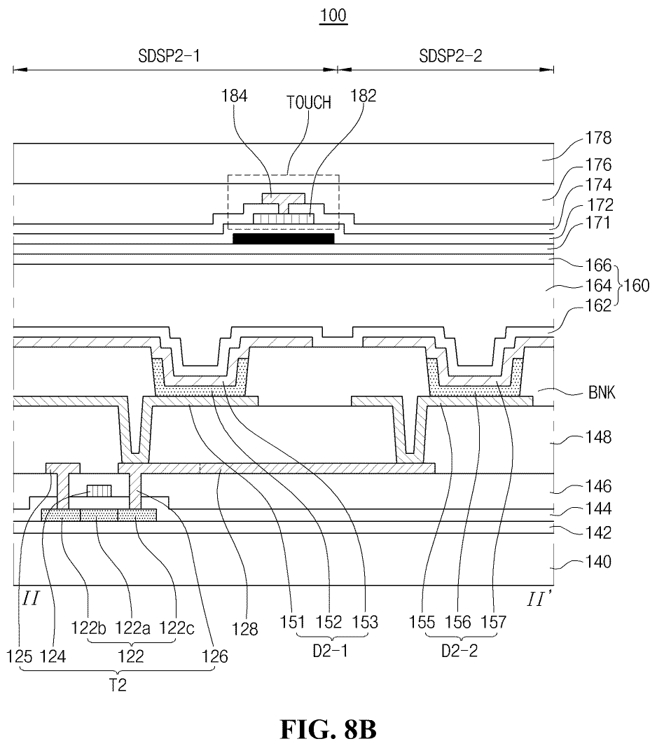

In the display apparatus, when the switching thin film transistor Ts is turned on by a gate signal applied to the gate line GL, a data signal applied to the data line DL is applied to a gate electrode of the driving thin film transistor Td (for example, the gate electrodes 115 and 125 in FIGS. 8A and 8B) and one electrode of the storage capacitor Cst through the switching thin film transistor Ts.

The driving thin film transistor Td is turned on by the data signal applied to its gate electrode (for example, the gate electrode 125 in FIG. 8B) so that a current proportional to the data signal is supplied from the power line PL to the light-emitting diode D through the driving thin film transistor Td. And then, the light-emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td (for example, the gate electrode 125 in FIG. 8B) is kept constant during one frame. Therefore, the display apparatus 100 can display a desired image.

In FIG. 3, the display apparatus 100 includes two thin film transistors Ts and Td and one storage capacitor Cst in the sub-pixel SP. However, the display apparatus 100 can comprise three or more thin film transistors and two or more storage capacitors.

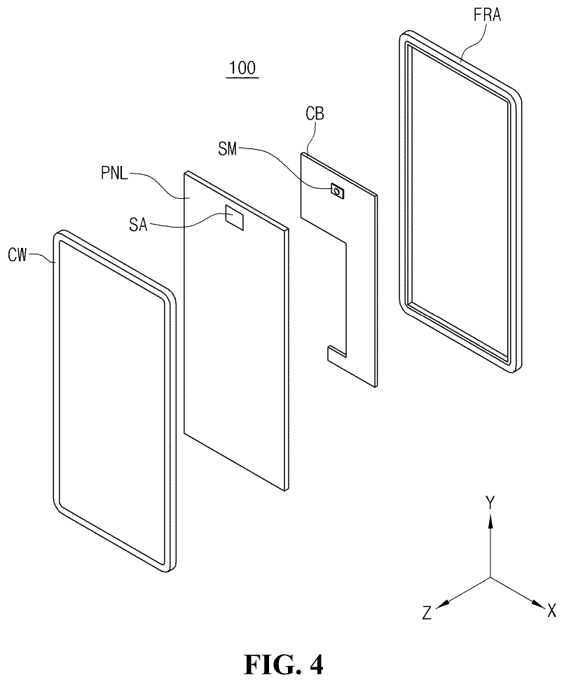

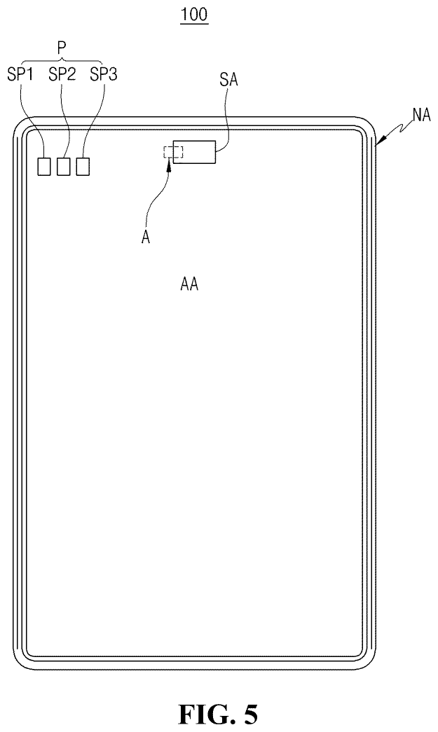

FIG. 4 illustrates an exploded perspective view of the display apparatus in accordance with an embodiment of the present disclosure. FIG. 5 illustrates a plane view of a display panel of the display apparatus in accordance with an embodiment of the present disclosure.

As illustrated in FIG. 4, the display apparatus 100 in one embodiment of the present disclosure comprises a display panel PNL, a sensor module SM, a circuit board CB, a cover window CW and a frame FRA. As illustrated in FIG. 5, the display panel PNL (FIG. 4) can comprise a display area AA in which an image is displayed and a non-display area NA disposed outside of the display area AA.

A pixel area P including a plurality of sub-pixels SP1, SP2 and SP3 is arranged in the display area AA. The sub-pixels SP1, SP2 and SP3 can comprise a red (R) sub-pixel, a green (G) sub-pixel and a blue (B) sub-pixel, respectively. Alternatively or additionally, the pixel area P can further comprise a white (W) sub-pixel.

A plurality of gate lines GLs and a plural data lines DLs are arranged in the display area AA. Each of the sub-pixels SP1, SP2 and SP3 is arranged on a crossing area of the gate line GL and the data lines DL. A thin film transistor as a switching element and a display device for implementing an image can be disposed within each sub-pixel SP1, SP2 or SP3.

The display device can comprise various display devices. For example, the display device can comprise, but is not limited to, an organic light-emitting display device, a liquid crystal display device, a quantum-dot display device, a micro LED (light-emitting diode) display device and a mini LED display device.

The gate driver 106 (FIG. 1) and the data driver 107 (FIG. 1) applying various signals to the display panel PNL can be disposed in the non-display area NA. The gate driver 106 applies the scan signal to the sub-pixels SP1, SP2 and SP3 through the gate line GL and the data driver 107 applies an image signal to the sub-pixels SP1, SP2 and SP3 through the data line DL. In one embodiment, the gate driver 106 can be, but is not limited to, a Gate-In-Panel (GIP) circuit in which gate driving circuits are disposed directly on a substrate.

The sensor module SM can be disposed on a rear side of the display panel PNL. In one embodiment, the sensor module SM can be disposed to overlap with the display area AA of the display panel PNL. The sensor module SM can indicate all components using external inputs input through the display panel PNL. As an example, the sensor module SM can comprise, but is not limited to, a camera, a light sensor, a fingerprinting sensor and the like.

In one embodiment, the display apparatus 100 can be a UDC (Under Display Camera)-type or a UDIR (Under Display IR)-type display apparatus where the sensor module SM is placed under the display panel PNL.

In a conventional display apparatus, a notch is formed in an upper part of the display area AA, and then an optical sensor such as a camera or an infrared sensor is placed in the notch. However, in this case, since the notch is formed by removing a portion of the upper part of the display area AA, not only the area of the display area AA is reduced, but there is also a problem in that it is aesthetically poor.

In order to solve those problems, a display apparatus in which a hole is formed in the display area AA and then an optical sensor is placed in the hole is proposed. However, in this case, since the hole is an area where an image is not displayed, there is a problem that the image are cut off or interrupted in the hole.

On the other hand, since the sensor module SM of the optical sensor is mounted under the display panel PNL in the display apparatus 100, it is possible to prevent the display area AA from being reduced or the image from being cut off.

The circuit board CB can be disposed on a rear surface of the display panel PNL. In one embodiment, the circuit board CB can comprise, but is not limited to, a printed circuit board (PCB) and/or a flexible printed circuit board (FPCB).

The cover window CW can be disposed on an upper surface of the display panel PNL. The cover window CW covers the entire surface of the display panel PNL to protect the display panel PNL from external impacts.

In one embodiment, the cover window CW can comprise, but is not limited to, a plastic material, a glass material and/or a reinforced glass material. For example, the cover window CW can comprise one of Sapphire Glass and Gorilla Glass, or can have a lamination structure of Sapphire Glass and Gorilla Glass. Alternatively or additionally, the cover window CW can comprise, but is not limited to, polyethylenetherephthalate (PET), polycarbonate (PC), polyethersulfone (PES), polyethylenenaphthalate (PEN), polynorbonene (PNB), and combinations thereof. In another embodiment, the cover window CW can comprise a reinforced glass considering scratches and/or transparency.

The frame FRA accommodates the display panel PNL and supports the cover window CW. In addition, the frame FRA accommodates the sensor module SM and the circuit board CB. The frame FRA enables the display panel PNL, the sensor module SM and the circuit board CB to be fixed to the display apparatus 100 and protects those components from external impacts.

As illustrated in FIG. 5, a sensor area SA is defined or formed in the display panel PNL (FIG. 4). The sensor area SA is aligned with the sensor module SM and transfers stimulus such as light input from the outside to the sensor module SM as it is. In one embodiment, a plurality of sub-pixels that display an image are provided in the sensor area SA to transmit external light to the sensor module SM and to display an image on the display panel PNL simultaneously.

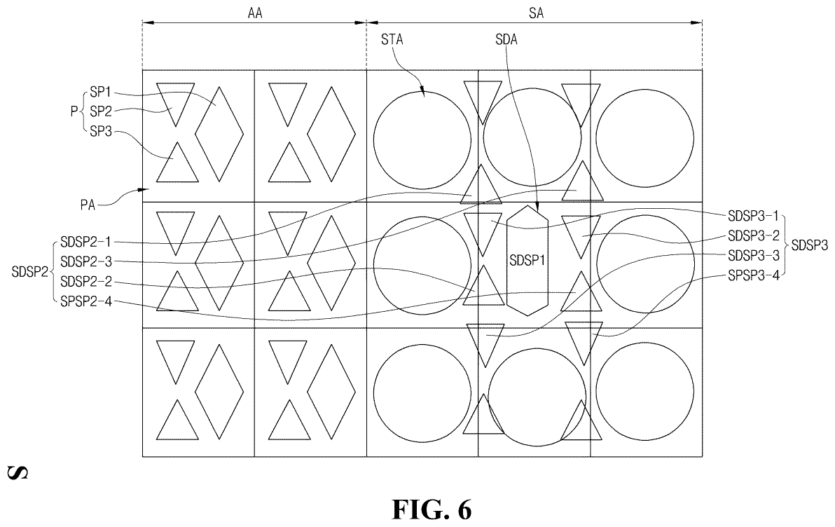

FIG. 6 illustrates a plane view enlarging an area “A” in FIG. 5 to indicate the display area AA and a sensor area SA conceptually.

As illustrated in FIG. 6, the display area AA comprises a plurality of pixel area PAs. Each pixel area PA comprises a pixel P with a plurality of sub-pixels SP1, SP2 and SP3. The sensor area SA can comprise a sensor display area SDA and a sensor transparent area STA. The sensor display area SDA is an area where an image is displayed within the sensor area SA, and the sensor transparent area STA is an area through which the external stimulus, such as external light, is transmitted and input to the sensor module SM. The sensor display area SDA comprises a plurality of sensor sub-pixels SDSP1, SDSP2 and SDSP3 forming a sensor display area pixel. A size of a sensor display area pixel may be greater than a size of a display area pixel.

In one embodiment, an overall area of the sub-pixels SP1, SP2 and SP3 of the pixel area PA in the display area AA can be substantially the same as an overall light-emitting area where light emits actually. Therefore, a plurality of the sub-pixels SP1, SP2 and SP3 can be the actual light-emitting area within the display area AA.

On the contrary, a light-emitting area within the sensor area SA is not limited within the sensor display area SDA, but is extended to a boundary area between the sensor display area SDA and the sensor transparent area STA, and optionally, to a certain area of the sensor transparent area STA. Accordingly, the sensor sub-pixels SDSP1, SDSP2 and SDSP3 illustrated in FIG. 6 (one or more of which may extend to even the sensor transparent area STA) can be the light-emitting area corresponding to the sensor display area SDA.

Hereinafter, the sub-pixels SP1, SP2 and SP3 can be defined as the pixel area PA of the display area AA, and the sensor sub-pixels SDSP1, SDSP2 and SDSP3 can be defined as the light-emitting area in the sensor display area SDA of the sensor area SA.

The plural sub-pixels SP1, SP2 and SP3 within the pixel area PA can be, but is not limited to, a red (R) sub-pixel, a green (G) sub-pixel and a blue (B) sub-pixel, respectively. Alternatively or additionally, the plural sub-pixels SP1, SP2 and SP3 can further comprise a white (W) sub-pixel. The plural sensor sub-pixels SDSP1, SDSP2 and SDSP3 within the sensor display area SDA can be, but is not limited to, a red (R) sub-pixel, a green (G) sub-pixel and a blue (B) sub-pixel. Alternatively or additionally, the plural sensor sub-pixels SDSP1, SDSP2 and SDSP3 can further comprise a white (W) sub-pixel.

In FIG. 6, taking four grids in the upper left corner of the sensor area SA as an example, one sensor display area SDA and three sensor transparent areas STAs are illustrated as an example of the arrangement as to the numbers of the sensor display area(s) SDA and the sensor transparent area(s) STA in the entire sensor area SA, but the configuration of those areas are not limited thereto. In another embodiment, the sensor area SA can comprise two or three sensor display areas SDAs and one or two sensor transparent areas STAs. When the sensor area SA includes two sensor display areas SDAs and one sensor transparent area STA, a problem may occur in detecting light through the sensor area SA. In one embodiment, the sensor area SA can comprise one sensor display area SDA and three sensor transparent areas STAs in the display apparatus 100. In one embodiment, one sensor area SA comprises at least four sensor transparent areas STA.

The sub-pixels SP1, SP2 and SP3 within the display area AA and/or the sensor sub-pixels SDSP1, SDSP2 and SDSP3 within the senor display area SDA can have various shapes and/or configurations. For example, the first sub-pixel SP1 can have a rhombus shape, each of the second and third sub-pixels SP2 and SP3 and the second and third sensor sub-pixels SDSP2 and SDSP3 can have a triangle shape, and the first sensor sub-pixel SDSP1 can have a hexagonal shape with long sides. However, the shapes of the sub-pixels SP1, SP2 and SP3 and the sensor sub-pixels SDSP1, SDSP2 and SDSP3 are not limited thereto, and can have various shapes.

As described above, the sensor area SA comprises the sensor display area SDA where the image is displayed and the sensor transparent area STA in the display apparatus 100 with the UDC structure and/or the UDIR structure. Therefore, the image can be displayed and external light can be detected simultaneously within the sensor area SA. Accordingly, compared to the configuration where the sensor is disposed to the notch and/or the configuration where the hole is formed within the display area, it is possible to prevent the display area AA from being reduced or the image from being cut off.

However, there are the following problems in the display apparatus with the UDC structure or the UDIR structure.

As described above, the image is displayed in the sensor area SA to prevent the image from being cut off in the display apparatus with the UDC or UDIR structure. However, it is necessary that the brightness in the display area AA and the brightness of the sensor area SA is maintained almost the same so that the user does not perceive the differences in brightness in each area in order to prevent the image from being cut off.

Both the sensor display area SDA where the image is displayed and the sensor transparent area STA that detects light are arranged in the sensor area SA in the display apparatus with the UDC or UDIR structure. Therefore, the brightness of the sensor display area SDA within the sensor area SA should be set higher than the brightness of the pixel area PA within the display area AA to make the brightness of the sensor area SA, where only a very small area displays the image, match the brightness of display area AA, where most of the area is the image display area.

For example, assuming that the areas of the sensor display area SDA and the sensor transparent area STA are basically the same, when the sensor area SA includes one sensor display area SDA and three sensor transparent areas STAs, the brightness of the sensor display area SDA within the sensor area SA should be four times as the brightness of the pixel area PA within the display area AA. Alternatively, when the sensor area SA includes three sensor display areas SDAs and one sensor transparent area STA, the brightness of the sensor display area SDA within the sensor area SA should be about 1.3 times as the brightness of the pixel area PA within the display area AA.

As such, the amount of current supplied to the sensor display area SDA should be significantly increased (for example, supplying four times current compared to the pixel area PA) in order to increase the brightness of the sensor display area SDA within the sensor area SA more than the brightness of the pixel area PA within the display area AA. In this case, the lifespan of the light-emitting diode within the sensor area SA can be shortened owing to the current increase.

The present disclosure provides a structure that maximizes the area of the sensor display area SDA within the sensor area SA to enhance the brightness within the sensor area SA but that does not reduce transmittance within the sensor transparent area STA.

As illustrated in FIG. 6, if regarding a center grid in the sensor area SA in FIG. 6 as a sensor display area SDA in a relatively narrow definition, one first sensor sub-pixel SDSP1, four second sensor sub-pixels SDSP2 or third sensor sub-pixels SDSP3 are arranged within one sensor display area SDA (that is, the second sensor sub-pixels SDSP2-2 and SDSP2-4 and the third sensor sub-pixels SDSP3-1 and SDSP3-2). The first sensor sub-pixel SDSP1 may be directly surrounded by a plurality of sensor transparent areas STA. For example, the first sensor sub-pixel SDSP1 may be directly adjacent to at least four sensor transparent areas STA. The second sensor sub-pixels SDSP2 and the third sensor sub-pixels SDSP3 may be directly adjacent to the first sensor sub-pixel SDSP1.

Additionally, as illustrated in FIG. 6, the light-emitting area within the sensor area SA is not limited to the sensor display area SDA in the narrow definition above; instead, it can extend to be close to the sensor transparent area STA, thus including, for example, the second sensor sub-pixels SDSP2-1 and SDSP2-3, and/or including, for example, the third sensor sub-pixels SDSP3-3 and SDSP3-4. In other words, in a more general definition, one first sensor sub-pixel SDSP1, four second sensor sub-pixels SDSP2 and third sensor sub-pixels SDSP3 can be arranged within one sensor display area SDA. Note that this general definition is merely exemplary and can be changed according to the pixel arrangement or layout. For example, if the four grids in the upper left of the sensor area SA are considered, these grids can also be regarded as showing a sensor display area SDA of the general definition and three sensor transparent areas STA, wherein eight second and third sensor sub-pixels, each shown as a triangle, and one first sensor sub-pixel SDSP1 are arranged in the broad sensor display area SDA.

In one embodiment, each of the plural second sensor sub-pixels SDSP2-1, SDSP2-2, SDSP2-3 and SDSP2-4 can be arranged outside of the first sensor sub-pixel SDSP1. Each of the plural third sensor sub-pixels SDSP3-1, SDSP3-2, SDSP3-3 and SDSP3-4 can be arranged outside of the first sensor sub-pixel SDSP1.

Comparing the sub-pixels SP1, SP2 and SP3 within the display area AA to the sensor sub-pixels SDSP1, SDSP2 and SDSP3 within the sensor area SA, the first sensor sub-pixel SDSP1 has an area greater than an area of the first sub-pixel SP1. However, each of the second and third sensor sub-pixels SDSP2 and SDSP3 can have an area that is substantially a same as an area of the second and third sub-pixels SP2 and SP3, respectively. While only one second sub-pixel SP2 and one third sub-pixel SP3 are arranged in one pixel area PA within the display area AA, four second sensor sub-pixels SDSP2 or third sensor sub-pixels SDSP3 (i.e. the sum of the number of the second sub-pixels and the third second sub-pixels is four) are arranged in one narrowly defined sensor display area SDA of the sensor area SA; and four second sensor sub-pixels SDSP2 and four third sensor sub-pixels SDSP3 (i.e. the sum of the number of the second sub-pixels and the third second sub-pixels is eight) are arranged in one generally-defined sensor display area SDA of the sensor area SA. Accordingly, each of the areas of the second and third sensor sub-pixels SDSP2 and SDSP3 within one generally-defined sensor display area SDA of the sensor area SA is approximately four times as each of the areas of the second and third sub-pixels SP2 and SP3 of one pixel area PA whose area is the same as the sensor display area SDA within the display area AA, respectively.

The amount of light emitted from the sensor sub-pixels SDSP1, SDSP2 and SDSP3 can be increased. Therefore, it is possible to increase significantly the brightness which the sensor sub-pixels SDSP1, SDSP2 and SDSP3 bring without increasing current.

In one embodiment, the sensor sub-pixels SDSP1, SDSP2 and SDSP3 can be arranged in the sensor display area SDA within the sensor area SA. In another embodiment, at least one of the sensor sub-pixels SDSP1, SDSP2 and SDSP3 can be extended to the boundary area between the sensor display area SDA and the sensor transparent area STA. In another embodiment, at least one of the sensor sub-pixels SDSP1, SDSP2 and SDSP3 can be extended to a certain area of the sensor transparent area STA.

In FIG. 6, four second sensor sub-pixels SDSP2 and four third sensor sub-pixels SDSP3 are arranged in one (generally-defined) sensor display area SDA. In another embodiment, two or three second sensor sub-pixels SDSP2 and/or two or three third sensor sub-pixels SDSP3 are arranged in one (generally-defined) sensor display area SDA. In another embodiment, five or more second sensor sub-pixels SDSP2 and/or five or more third sensor sub-pixels SDSP3 are arranged in one (generally-defined) sensor display area SDA. In another embodiment, different numbers of the second sensor sub-pixels SDSP2 and the third sensor sub-pixels SDSP3 are arranged in one sensor display area SDA.

In one embodiment, each of the first to third sub-pixels SP1, SP2 and SP3 in the pixel area PA and each of the first to third sensor sub-pixels SDSP1, SDSP2 and SDSP3 in the sensor display area SDA can emit corresponding color light, respectively. In another embodiment, each of the first to third sub-pixels SP1, SP2 and SP3 in the pixel area PA and each of the first to third sensor sub-pixels SDSP1, SDSP2 and SDSP3 in the sensor display area SDA can emit different color light, respectively. For example, the first to third sub-pixels SP1, SP2 and SP3 can emit red light, green light and blue light, respectively, and the first to third sensor sub-pixel SDSP1, SDSP2 and SDSP3 can emit red light, green light and blue light, respectively. Alternatively, the first to third sub-pixels SP1, SP2 and SP3 can emit red light, green light and blue light, respectively, and the first to third sensor sub-pixel SDSP1, SDSP2 and SDSP3 can emit blue light, green light and red light, respectively. It is possible to design the first to third sensor sub-pixels SDSP1, SDSP2 and SDSP3 differently depending the areas and the likes of the first to third sensor sub-pixels SDSP1, SDSP2 and SDSP3.

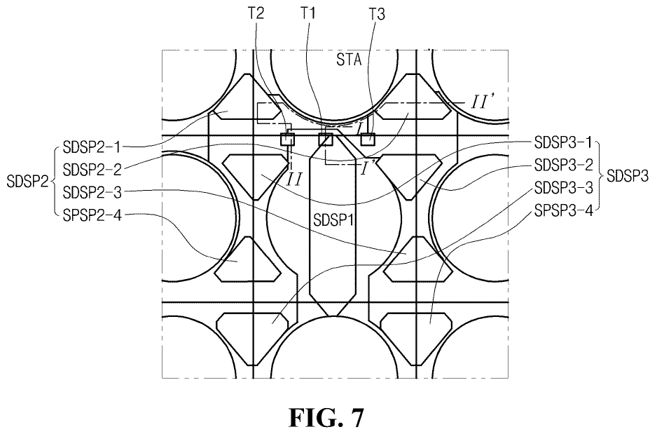

FIG. 7 illustrates a schematic plane view of sensor sub-pixels of the display apparatus in accordance with an embodiment of the present disclosure.

As illustrated in FIG. 7, a plurality of sensor sub-pixels SDSP1, SDSP2 and SDSP3 are disposed in the sensor display area SDA within the sensor area SA. As an example, the first sensor sub-pixel SDSP1 is arranged in the central area of the sensor display area SDA, and each of the plurality of second sensor sub-pixels SDSP2 and the plurality of third sensor sub-pixels SDSP3 are arranged around the first sensor sub-pixel SDSP1.

In one embodiment, the first sensor sub-pixel SDSP1 is arranged longitudinally along a vertical direction in the central area of the sensor area SA, so that a part of the upper and lower portions of the first sensor sub-pixel SDSP1 can be extended to the boundary area between the sensor display area SDA and the sensor transparent area STA, or can be extended to a part of the sensor transparent area STA. Alternatively, the first sensor sub-pixel SDSP1 can be formed or arranged within the sensor display area SDA.

In one embodiment, each of the second sensor sub-pixels SDSP2 and the third sensor sub-pixels SDSP3 can be extended to the boundary area of the sensor transparent area STA adjacent to the sensor display area SDA, or extended to the part of the sensor transparent area STA.

The second sensor sub-pixel SDSP2 can comprise, but is not limited to, four senor sub-pixels SDSP2-1, SDSP2-2, SDSP2-3 and SDSP2-4, and the third sensor sub-pixel SDSP3 can comprise, but is not limited to, four sensor sub-pixels SDSP3-1, SDSP3-2, SDSP3-3 and SDSP3-4.

The sensor display area SDA can be defined by plural gate lines and data lines disposed vertically and horizontally. Each of the gate lines and data lines can be electrically connected to each of the first to third sensor sub-pixels SDSP1, SDSP2 and SDSP3.

The sensor transparent area STA is an area through which light is transmitted and input the light to the sensor module SM (FIG. 4). The transparency of the sensor transparent area STA must be maximized so as to improve the sensing efficiency of the sensor module SM. Accordingly, the gate line and the data line can be formed on the outside of the sensor transparent area STA. In addition, for the convenience of design, the gate line and the data line arranged in the sensor display area SDA can also be arranged in the same manner as the sensor transparent area STA, but is not limited thereto.

As illustrated in FIG. 7, a first thin film transistor T1 is electrically connected to the first sensor sub-pixel SDSP1 so that external signals can be applied to the first sensor sub-pixel SDSP1 through the first thin film transistor T1. Also, a second thin film transistor T2 is electrically connected to the second sensor sub-pixel SDSP2 so that external signals can be applied to the second sensor sub-pixel SDSP2 through the second thin film transistor T2. In addition, a third thin film transistor T3 is electrically connected to the third sensor sub-pixel SDSP3 so that external signals can be applied to the third sensor sub-pixel SDSP3 through the third thin film transistor T3.

The plural second sensor sub-pixels SDSP2-1, SDSP2-2, SDSP2-3 and SDSP2-4 share the second thin film transistor T2 so that external signals can be applied simultaneously to the plural second sensor sub-pixels SDSP2-1, SDSP2-2, SDSP2-3 and SDSP2-4 though the second thin film transistor T2. The external signals can be applied simultaneously to the plural second sub-pixels SDSP2-1, SDSP2-2, SDSP2-3 and SDSP2-4 by a first connecting electrode 128a that is electrically connected to the plural second sub-pixels SDSP2-1, SDSP2-2, SDSP2-3 and SDSP2-4. An identical signal is applied to the plural second sensor sub-pixels SDSP2-1, SDSP2-2, SDSP2-3 and SDSP2-4 arranged in one sensor display area SDA in each of which the same image is displayed.

The plural third sensor sub-pixels SDSP3-1, SDSP3-2, SDSP3-3 and SDSP3-4 share the third thin film transistor T3 so that external signals can be applied simultaneously to the plural third sensor sub-pixels SDSP3-1, SDSP3-2, SDSP3-3 and SDSP3-4 though the third thin film transistor T3. The external signals can be applied simultaneously to the plural third sub-pixels SDSP3-1, SDSP3-2, SDSP3-3 and SDSP3-4 by a second connecting electrode 128b that is electrically connected to the plural third sub-pixels SDSP3-1, SDSP3-2, SDSP3-3 and SDSP3-4. An identical signal is applied to the plural third sensor sub-pixels SDSP3-1, SDSP3-2, SDSP3-3 and SDSP3-4 arranged in one sensor display area SDA in each of which same image is displayed.

As such, plural second sensor sub-pixels SDSP2 and plural third sensor sub-pixels SDSP3 are arranged in one sensor display area SDA in the display apparatus 100. As the emitting-area increases, the brightness of the sensor display area SDA can be improved.

As the plural sensor sub-pixels SDSP2 and SDSP3 shares one thin film transistor T2 or T3, it is possible to minimize the area occupied by the thin film transistor and to reduce fabrication cost.

FIG. 8A illustrates a cross-sectional view taken along a line I-I′ in FIG. 7. FIG. 8B illustrates a cross-sectional view taken along a line II-II′ in FIG. 7. FIG. 8A is a cross-sectional view of the first sensor sub-pixel SDSP1, and FIG. 8B is a cross-sectional view of the second sensor sub-pixel SDSP2. In FIG. 8B, for the convenience of explanation, only two second sensor sub-pixels SDSP2-1 and SDSP2-2 instead of four second sensor sub-pixels SDSP2 are illustrated. In addition, since the structure of the third sensor sub-pixel SDSP3 is the same as the structure of the second sensor sub-pixel SDSP2, the description of the structure of the third sensor sub-pixel SDSP3 is replaced by explaining the structure of the second sensor sub-pixel SDSP2.

As illustrated in FIGS. 8A and 8B, a first buffer layer 142 is disposed on an entire substrate 140 including the first sensor sub-pixel SDSP1 and the second sensor sub-pixels SDSP2-1 and SDSP2-2. The substrate 140 can comprise hard material such as glass and/or flexible plastics material.

When the substrate 140 comprises the plastics material, the substrate 140 can comprise, but is not limited to, polyimide (PI), polymethylmethacrylate (PMMA), polyethylene terephthalate (PET), polyether sulfone (PS), polycarbonate (PC) and combinations thereof.

For example, when the substrate 140 comprises polyimide, the substrate can have multiple layers each of which comprise polyimide, and an inorganic layer can be disposed between those polyimide substrates, but is not limited thereto.

A first buffer layer 142 is disposed on the entire substrate 140. The first buffer layer 142 can improve adhesive forces between the substrate 140 and the layers disposed on the substrate 140, and play a role in blocking alkali components leaking from the substrate 140. In addition, the first buffer layer 142 can delay the diffusion of moisture and/or oxygen penetrated into the substrate 140.

In one embodiment, the first buffer layer 142 can have a mono-layer structure or a multi-layer structure of inorganic material such as SiNₓ or SiOₓ (wherein, 0<x≤2). In one embodiment, the first buffer layer 142 has the multi-layer structure in which a layer of SiOₓ and a layer of SiNₓ are alternately disposed. In some embodiments, the first buffer layer 142 can be omitted considering the kinds and materials of the substrate 140, the structure and types of the thin film transistor.

A first thin film transistor T1 in the first sensor sub-pixel SDSP1 and a second thin film transistor T2 in the second sensor sub-pixel SDSP2 are disposed on the first buffer layer, respectively. For the convenience of explanation, only a driving thin film transistor among various thin film transistors that can be arranged in the display area AA and/or the sensor area SA is indicated on the first buffer layer 142 in FIGS. 8A and 8B, but other thin film transistors such as a switching thin film transistor can also be disposed on the first buffer layer 142. In FIGS. 8A and 8B, while the first and second thin film transistors T1 and T2 with a Top Gate structure are illustrated, the thin film transistors T1 and T2 can have another structure such as a Bottom Gate structure.

While the second thin film transistor T2 is formed in the second-first sensor sub-pixel SDSP2-1, the second thin film transistor T2 is shared by the second-first sensor sub-pixel SDSP2-1 and the second-second sensor sub-pixel SDSP2-2. In FIG. 8B, the second thin film transistor T2 is disposed in the second-first sensor sub-pixel SDSP2-1, but the second thin film transistor T2 can be disposed in the second-second sensor sub-pixel SDSP2-2 alternatively. In addition, the second thin film transistor T2 can be disposed in the second-third sensor sub-pixel SDSP2-3 and the second-fourth sensor sub-pixel SDSP2-4.

The first thin film transistor T1 can comprise a first semiconductor layer 112 disposed on the first buffer layer 142, a gate insulating layer 144 disposed on the first semiconductor layer 112, a first gate electrode 114 disposed on the gate insulating layer 144, a first interlayer insulating layer 146 disposed on the first gate electrode 114, and a first source electrode 115 and a first drain electrode 116 disposed on the first interlayer insulating layer 146.

The second thin film transistor T2 can comprise a second semiconductor layer 122 disposed on the first buffer layer 142, a gate insulating layer 144 disposed on the second semiconductor layer 122, a second gate electrode 124 disposed on the gate insulating layer 144, a first interlayer insulating layer 146 disposed on the second gate electrode 124, and a second source electrode 125 and a second drain electrode 126 disposed on the first interlayer insulating layer 146.

In one embodiment, each of the first semiconductor layer 112 and the second semiconductor layer 122 can comprise a polycrystalline semiconductor. For example, the polycrystalline semiconductor can comprise, but is not limited to, Low Temperature Poly Silicon (LTPS) with high mobility.

In another embodiment, each of the first semiconductor layer 112 and the second semiconductor layer 122 can comprise oxide semiconductor. For example, each of the first and second semiconductor layers 112 and 122 can independently comprise, but is not limited to, Indium-gallium-zinc oxide (IGZO), indium-zinc oxide (IZO), indium-gallium-tin oxide (IGTO) and/or indium-gallium oxide (IGO). The first semiconductor layer 112 can comprise a first channel area 112a of the central area, and a first source area 112b and a first drain area 112c of doping layers at both sides. The second semiconductor layer 122 can comprise a second channel area 122a of the central area, and a second source area 122b and a second drain area 122c of doping layers at both sides.

In one embodiment, the first semiconductor layer 112 can comprise the same material as the second semiconductor layer 122. In another embodiment, the first semiconductor layer 112 can comprise different material from the second semiconductor layer 122.

The gate insulating layer 144 can comprise, but is not limited to, inorganic material such as SiOₓ and SiNₓ (wherein, 0<x≤2). The gate insulating layer 144 can have a mono-layer structure or a multi-layer structure.

Each of the first gate electrode 114 and the second gate electrode 124 can comprise metal. For example, each of the first gate electrode 114 and the second gate electrode 124 can independently comprise, but is not limited to, molybdenum (Mo), aluminum (Al), chrome (Cr), gold (Au), titanium (Ti), nickel (Ni), neodymium (Nd), copper (Cu), combinations thereof and/or alloys thereof. Each of the first gate electrode 114 and the second gate electrode 124 can have a mono-layer structure or a multi-layer structure.

The first interlayer insulating layer 146 can comprise organic material such as photo-acryl or inorganic material such as SiNₓ and/or SiOₓ (wherein, 0<x≤2). The first interlayer insulating layer 146 can have a mono-layer structure or a multi-layer structure. In another embodiment, the first interlayer insulating layer 146 can have, but is not limited to, a multi-layer structure of an organic layer and an inorganic layer.

Each of the first source electrode 115, the first drain electrode 116, the second source electrode 125 and the second drain electrode 126 can independently comprise, but is not limited to, molybdenum (Mo), aluminum (Al), chrome (Cr), gold (Au), titanium (Ti), nickel (Ni), neodymium (Nd), copper (Cu), combinations thereof and/or alloys thereof. Each of the first source electrode 115, the first drain electrode 116, the second source electrode 125 and the second drain electrode 126 can have a mono-layer structure or a multi-layer structure, respectively.

The first source electrode 115 and the first drain electrode 116 can be contacted to the first source area 112b and the first drain area 112c, respectively, of the first semiconductor layer 112 through contact holes formed in the gate insulating layer 144 and the first interlayer insulating layer 146. The second source electrode 125 and the second drain electrode 126 can be contacted to the second source area 122b and the second drain area 122c, respectively, of the second semiconductor layer 122 through contact holes formed in the gate insulating layer 144 and the first interlayer insulating layer 146.

In one embodiment, a bottom shield metal layer is disposed between the substrate 140, and the first semiconductor layer 112 and the second semiconductor layer 122. The bottom shield metal layer minimizes the back-channel phenomenon caused by charges trapped in the substrate 140 and prevents afterimages or degradation of transistor performance. For example, the bottom shield metal layer can comprise, but is not limited to, titanium (Ti), molybdenum (Mo), combinations thereof and/or alloys thereof. The bottom shield metal layer can have a mono-layer structure or a multi-layer structure.

A passivation layer 148 is disposed on the substrate 140 over which the first thin film transistor T1 and the second thin film transistor T2 are disposed. In one embodiment, the passivation layer 148 can comprise, but is not limited to, an organic material such as photo-acryl. In another embodiment, the passivation layer 148 can comprise multiple layers comprising an inorganic layer and/or an organic layer.

A first light-emitting diode D1 is disposed on the passivation layer 148 in the first sensor sub-pixel SDSP1, a second light-emitting diode D2-1 is disposed on the passivation layer 148 in the second-first sensor sub-pixel SDSP2-1, and another second light-emitting diode D2-2 is disposed on the passivation layer 148 in the second-second sensor sub-pixel SDSP2-2.

The first light-emitting diode D1 can comprise a first anode electrode 132, a first emissive layer 134 and a first cathode electrode 136. The second light-emitting diode D2-1 can comprise a second anode electrode 151, a second emissive layer 152 and a second cathode electrode 153. The other second light-emitting diode D2-2 can comprise a second anode electrode 155, a second emissive layer 156 and a second cathode electrode 157. Since in some embodiments each sensor display area pixel only comprises a single first light-emitting diode D1, each sensor sub-pixel may comprise a single emissive layer only.

The first anode electrode 132 of the first light-emitting diode D1 is disposed on the passivation layer 148 and can be electrically connected to the first drain electrode 116 of the first thin film transistor T1 though a contact hole formed in the passivation layer 148. The second anode electrode 151 of the second light-emitting diode D2-1 can be electrically connected to the second drain electrode 126 of the second thin film transistor T2.

The connecting electrode 128 is disposed on the first interlayer insulating layer 146. Alternatively or additionally, the connecting electrode 128 can be disposed on the passivation layer 148. In this case, the connecting electrode 128 may be disposed with the same process and/or the same materials as the second anode electrode 151, but is not limited thereto. The connecting electrode 128 is extended to the second-second sensor sub-pixel SDSP2-2 from the second-first sensor sub-pixel SDSP2-1 so that the second thin film transistor T2 disposed in the second-first sensor sub-pixel SDSP2-1 can be connected to the other second light-emitting diode D2-2 disposed in the second-second sensor sub-pixel SDSP2-2 through the connecting electrode 128. In one embodiment, the connecting electrode 128 can be formed integrally with the second drain electrode 126 of the second thin film transistor T2, but is not limited thereto.

The second anode electrode 155 of the second light-emitting diode D2-2 is electrically connected to the second drain electrode 126 of the second thin film transistor T2 through the contact holes formed in the passivation layer 148 and the connecting electrode 128 disposed on the passivation layer 148. In other words, both the second anode electrode 151 of the second light-emitting diode D2-1 and the second anode electrode 155 of the other second light-emitting diode D2-2 are electrically connected to the second drain electrode 126 of the second thin film transistor T2 so that the second light-emitting diode D2-1 and the other second light-emitting diode D2-2 can be driven simultaneously. Besides, the above description for the second sensor sub-pixel including the second light-emitting diodes (D2-1 and D2-2, which may be collectively referred to as D2) with respect to FIG. 8B similarly applies to the third sensor sub-pixel including the third light-emitting diode, though not illustrated in the figure.

Though not shown in the figure, a third light-emitting diode of the third sensor sub-pixel is disposed on the passivation layer 148 in the third sensor sub-pixel. The third light-emitting diode can comprise a third anode electrode, a third emissive layer and a third cathode electrode. In one embodiment, each of the first anode electrode 132, the second anode electrode 151 or 155 and the third anode electrode (not shown in the drawings) can independently comprise, but is not limited to, silver (Ag), aluminum (Al), gold (Au), tungsten (W), chrome (Cr), combinations thereof and/or alloys thereof. In another embodiment, each of the first anode electrode 132, the second anode electrode 151 or 155 and the third anode electrode can independently comprise, but is not limited to, a metal oxide material layer such as indium-tin oxide (ITO), indium-zinc oxide (IZO), and the like.

When the display apparatus 100 is a top-emission type display apparatus, each of the first anode electrode 132, the second anode electrode 151 or 155 and the third anode electrode can independently further comprise an opaque conductive material for acting as a reflective electrode reflecting light. Alternatively, when the display apparatus 100 is a bottom-emission type display apparatus, each of the first anode electrode 132, the second anode electrode 151 or 155 and the third anode electrode can be independently disposed using a transparent conductive material transmitting light such as indium-tin oxide (ITO), indium-zinc oxide (IZO) and the like.

A bank layer BNK is disposed in a boundary between the sub-pixels and sensor sub-pixels on the passivation layer 148. The bank layer BNK can be a kind of a bulkhead defining each sub-pixel and sensor sub-pixel. The bank layer BNK can partition each sub-pixel and sensor sub-pixel to prevent light of specific color output from adjacent sub-pixels from being mixed and output.

In one embodiment, The bank layer BNK is disposed in the boundary between the second-first sensor sub-pixel SDSP2-1 and the second-second sensor sub-pixel SDSP2-2 as illustrated in FIG. 8B. In another embodiment, any bank layer needn't be disposed in the boundary between the second-first sensor sub-pixel SDSP2-1 and the second-second sensor sub-pixel SDSP2-2 when the second-first sensor sub-pixel SDSP2-1 and the second-second sub-pixel SDSP2-2 emit the same color light.

The bank layer BNK can comprise, but is not limited to, an inorganic insulating material such as SiNₓ and/or SiOₓ (wherein, 0<x≤2), an organic insulating material such as benzocyclobutene (BCB), an acryl-containing resin, an epoxy-containing resin, a phenolic resin, a polyamide-containing resin, a polyimide-containing resin and combinations thereof, and a photosensitive material such as black pigment and/or dye.

The first emissive layer 134 is disposed on the first anode electrode 132 exposed by the bank layer BNK, an inclined surface of the bank layer BNK and at least a portion of an uppers surface of the bank layer BNK. Similarly, the second emissive layer 152 is disposed on the second anode electrode 151 exposed by the bank layer BNK, an inclined surface of the bank layer BNK and at least a portion of an uppers surface of the bank layer BNK. The second emissive layer 156 is disposed on the second anode electrode 155 exposed by the bank layer BNK, an inclined surface of the bank layer BNK and at least a portion of an uppers surface of the bank layer BNK.

In one embodiment, the second emissive layer 152 disposed in the second-first sensor sub-pixel SDSP2-1 is spaced apart from the second emissive layer 156 disposed in the second-second sensor sub-pixel SDSP2-2 as illustrated in FIG. 8B. In another embodiment, the second emissive layer 152 disposed in the second-first sensor sub-pixel SDSP2-1 can be integral with the second emissive layer 156 disposed in the second-second sensor sub-pixel SDSP2-2. Besides, the above description for the second emissive layers 152 and 156 of the second sensor sub-pixel with respect to FIG. 8B similarly applies to the third emissive layers of the third sensor sub-pixel, though not shown in the drawings.

In one embodiment, each of the first emissive layer 134, the second emissive layer 152 or 156 and the third emissive layer (not shown in the drawings) can independently comprise a red (R) emissive layer emitting red light disposed in the red sub-pixel, a green (G) emissive layer emitting green light disposed in the green sub-pixel and a blue (B) emissive layer emitting blue light disposed in the blue sub-pixel. For example, each of the first emissive layer 134, the second emissive layer 152 or 156 and the third emissive layer can independently comprise, but is not limited to, an organic emissive layer, an inorganic emissive layer, a nano-sized emissive layer, a quantum dot emissive layer, a micro LED emissive layer and/or a mini LED emissive layer.

In one embodiment, each of the first emissive layer 134, the second emissive layer 152 or 156 and the third emissive layer can independently comprise an emitting material layer. In another embodiment, each of the first emissive layer 134, the second emissive layer 152 or 156 and the third emissive layer can independently further comprise, but is not limited to, a hole injection layer, a hole transport layer, an electron blocking layer, a hole blocking layer, an electron transport layer and/or an electron injection layer.

The first cathode electrode 136, the second cathode electrode 153 or 157 and the third cathode electrode (not shown in the drawings) can be disposed on the first emissive layer 134, the second emissive layer 152 or 156 and the third emissive layer (not shown in the drawings), respectively, and can have a mono-layer structure or a multi-layer structure including metal and/or metal alloy. Alternatively, each of the first cathode electrode 136, the second cathode electrode 153 or 157 and the third cathode electrode can independently comprise, but is not limited to, a transparent metal oxide such as indium-tin oxide (ITO), indium-zinc oxide (IZO) and the like.

In one embodiment, the first cathode electrode 136, the second cathode electrode 153 or 157 and the third cathode electrode can be formed integrally, but is not limited thereto. In another embodiment, the first cathode electrode 136, the second cathode electrode 153 or 157 and the third cathode electrode can be spaced apart from each other between sensor sub-pixels SDSP1, SDSP2 and SDSP3. That is to say that each cathode electrode 136, 153, 157 may be spaced apart from each other cathode electrode 136, 153, 157 in the sensor display area SDA. In another embodiment, the first cathode electrode 136, the second cathode electrode 153 or 157 and the third cathode electrode can be spaced apart from each other on the bank layer BNK (FIG. 8B).

In one embodiment, when the display apparatus 100 is a top-emission type display apparatus, each of the first cathode electrode 136, the second cathode electrode 153 or 157 and the third cathode electrode can be independently disposed using a semi-transparent conductive material transmitting light. For example, each of the first cathode electrode 136, the second cathode electrode 153 or 157 and the third cathode electrode can comprise, but is not limited to, a metal alloy such as LiF/Al, CsF: Al, Mg: Ag, Ca/Ag, Ca: Ag, LiF/Mg: Ag, LiF/Ca/Ag, LiF/Ca: Ag and combinations thereof.

In another embodiment, when the display apparatus 100 is a bottom-emission type display apparatus, each of the first cathode electrode 136, the second cathode electrode 153 or 157 and the third cathode electrode can be independently disposed using an opaque conductive material as a reflective electrode reflecting light. For example, each of the first cathode electrode 136, the second cathode electrode 153 or 157 and the third cathode electrode can independently comprise, but is not limited to, silver (Ag), aluminum (Al), gold (Au), molybdenum (Mo), tungsten (W), chrome (Cr), combinations thereof and/or alloys thereof.

In addition, each of the first light-emitting diode D1, the second light-emitting diode D2 and the third light-emitting diode can independently have a tandem structure. The tandem structure includes a plurality of light-emitting parts and at least one charge generation layer disposed between the light-emitting parts. Each of the light-emitting parts can comprise an emissive layer.

The charge generation layer adjusts charge balances between the plural light-emitting parts and can be a plurality of layers including a first charge generation layer and a second charge generation layer. For example, the charge generation layer can include an N-type charge generation layer and a P-type charge generation layer and can comprise a layer doped with an alkali metal such as Li, Na, K and/or Cs or an alkaline earth metal such as Mg, Sr, Ba and/or Ra, but is not limited thereto.

An encapsulation layer 160 is disposed on the first light-emitting diode D1, the second light-emitting diode D2 and/or the third light-emitting diode (not shown in the drawings) so that the first light-emitting diode D1, the second light-emitting diode D2 and the third light-emitting diode can be encapsulated by the encapsulation layer 160. When the first light-emitting diode D1, the second light-emitting diode D2 and the third light-emitting diode are exposed to moisture or oxygen, a pixel shrinkage phenomenon in which the light-emitting area is reduced or a defect in which a dark spot is formed within the light-emitting area may occur. In addition, moisture or oxygen oxidizes electrode made of a metal component. The encapsulation layer 160 blocks penetration of moisture and/or oxygen from the outside, thereby preventing defects in the first light-emitting diode D1, the second light-emitting diode D2, the third light-emitting diode and/or various electrodes.

In one embodiment, the encapsulation layer 160 can comprise, but is not limited to, a first encapsulation layer 162, a second encapsulation layer 164 and a third encapsulation layer 166. In another embodiment, the encapsulation layer 160 can consist of two layers or 4 or more layers.

Each of the first encapsulation layer 162 and the third encapsulation layer 166 can have, but is not limited to, a mono layer of an inorganic material such as SiOₓ, SiON and/or SiNₓ (wherein, 0 <x≤2), or multi-layers including the inorganic material. In another embodiment, each of the first encapsulation layer 162 and the third encapsulation layer 166 can further comprise, but is not limited to, at least one organic layer disposed between the inorganic layers of SiOₓ, SiON and/or SiNₓ (wherein, 0<x≤2). The second encapsulation layer 164 can comprise an organic material such as epoxy-containing resin.

A second buffer layer 171 is disposed on the encapsulation layer 160 and a light-shielding layer BM is disposed on the second buffer layer 171. The light-shielding layer BM corresponds to a touch electrode 184. In other embodiments, the light-shielding layer BM may be disposed on a layer above the second buffer layer 171. The light-shielding layer BM may overlap with a touch electrode 184. The second buffer layer 171 can comprise, but is not limited to, an inorganic material such as SiNₓ and/or SiOₓ (wherein, 0<x≤2). The second buffer layer 171 can have a mono-layer structure or a multi-layer structure. The light-shielding layer BM absorbs light. More particularly, the light-shielding layer BM blocks or absorbs light output to the adjacent sensor display area SDA and the sensor transparent area STA to prevent color mixing. The light-shielding layer BM can comprise, but is not limited to, a metal-containing material such as Cr and/or CrOₓ (wherein, 0<x≤2).

A second interlayer insulating layer 171 is disposed on the second buffer layer 172 where the light-shielding layer BM is positioned. A touch member TOUCH is disposed on the second interlayer insulating layer 172. The touch member TOUCH is disposed within the display area AA to sense a touch input. In one embodiment, the touch member TOUCH can sense an external touch information from user's finger and/or a touch pen.

The second interlayer insulating layer 172 blocks chemical solutions, such as a developer and/or etchant used in forming the touch member TOUCH, and/or external moisture or oxygen from penetrating into the first to third light-emitting diodes. In addition, the second interlayer insulating layer 172 can prevent a plurality of touch electrodes 184 arranged on the second interlayer insulating layer 172 from being short-circuited by external impact, and can block interference signals that may occur when the touch member TOUCH is driven.

In one embodiment, the second interlayer insulating layer 172 can comprise, but is not limited to, an organic material such as photo acryl or an inorganic material such as SiNₓ and/or SiOₓ (wherein, 0<x≤2). The second interlayer insulating layer 172 can have a mono-layer structure or a multi-layer structure. In another embodiment, the second interlayer insulating layer 172 can have, but is not limited to, multi layers of an organic layer and an inorganic layer

The touch member TOUCH can comprise a touch connecting electrode 182 disposed on the second interlayer insulating layer 172, a first passivation layer 174 disposed on the touch connecting electrode 182, a plurality of touch electrodes 184 disposed on the first passivation layer 174 and a second passivation layer 176 disposed on the touch electrode 184.

The touch electrode 184 is electrically connected to the touch connecting electrode 182 through a contact hole formed in the first passivation layer 174. The plural touch electrodes 184 are disposed on the first passivation layer 174 and the touch connecting electrode 182 electrically connects the adjacent plural touch electrodes 184.

In one embodiment, each of the touch connecting electrode 182 and the touch electrode 184 can independently comprise, but is not limited to, a transparent metal oxide such as indium-tin oxide (ITO), indium-zinc oxide (IZO) and the like. In another embodiment, each of the touch connecting electrode 182 and the touch electrode 184 can independently comprise, but is not limited to, a metal component such as molybdenum (Mo), aluminum (Al), chrome (Cr), gold (Au), titanium (Ti), nickel (Ni), neodymium (Nd), copper (Cu), combinations thereof and/or alloys thereof. Each of the touch connecting electrode 182 and the touch electrode 184 can have a mono-layer structure or a multi-layer structure.

In one embodiment, the second passivation layer 176 can comprise, but is not limited to, an organic material such as photo acryl. In another embodiment, the second passivation layer 176 can have multi layers including an inorganic layer and an organic layer.

As described above, the display apparatus 100 includes the plural sensor sub-pixels SDSP1, SDSP2 and SDSP3 within one sensor display area SDA so that the brightness of the sensor display area SDA can be increased as the light-emitting area increases. In addition, since the plural sensor sub-pixels SDSP2-1 and SDSP2-2 shared one thin film transistor T2, it is possible to minimize the area occupied by the thin film transistor T2 and to reduce the fabrication cost.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

1. A display apparatus, comprising:
a display panel comprising a display area and a sensor area within the display area, the sensor area comprising a sensor display area for displaying an image and a sensor transparent area for transmitting light;
a sensor module disposed on a lower surface of the display panel and aligned with the sensor area; and
a sensor display area pixel comprising a first sensor sub-pixel, a plurality of second sensor sub-pixels and a plurality of third sensor sub-pixels arranged in the sensor display area, wherein the first sensor sub-pixel is configured to display a first color, wherein the plurality of second sensor sub-pixels is configured to display a second color, and wherein the plurality of third sensor sub-pixels is configured to display a third color,
wherein the plurality of second sensor sub-pixels and the plurality of third sensor sub-pixels are arranged around the first sensor sub-pixel.

2. The display apparatus of claim 1, wherein the first sensor sub-pixel, the second sensor sub-pixels and the third sensor sub-pixels are configured to display red, green and blue, respectively.

3. The display apparatus of claim 1, wherein the first sensor sub-pixel is arranged in a central region of the sensor display area.

4. The display apparatus of claim 1, further comprising:
a first thin film transistor disposed in the first sensor sub-pixel;
a second thin film transistor disposed in the plurality of second sensor sub-pixels;
a third thin film transistor disposed in the plurality of third sensor sub-pixels;
a first light-emitting diode disposed in the first sensor sub-pixel;
a second light-emitting diode disposed in each of the plurality of second sensor sub-pixels; and
a third light-emitting diode disposed in each of the plurality of third sensor sub-pixels.

5. The display apparatus of claim 4, wherein the plurality of second sensor sub-pixels comprises:
a second-first sensor sub-pixel; and
a second-second sensor sub-pixel, and
wherein the plurality of third sensor sub-pixels comprises:
a third-first sensor sub-pixel; and
a third-second sub-pixel.

6. The display apparatus of claim 5, the display apparatus further comprising:
a first connection electrode electrically connected to the second-first sensor sub-pixel and the second-second sensor sub-pixel; and
a second connection electrode electrically connected to the third-first sensor sub-pixel and the third-second sensor sub-pixel.

7. The display apparatus of claim 6, wherein each of the first thin film transistor, the second thin film transistor and the third thin film transistor comprises:
a semiconductor layer;
a gate insulating layer disposed on the semiconductor layer;
a gate electrode disposed on the gate insulating layer;
an interlayer insulating layer disposed on the gate electrode; and
a source electrode and a drain electrode disposed on the interlayer insulating layer.

8. The display apparatus of claim 7, wherein the first connection electrode and the second connection electrodes are disposed on the interlayer insulating layer.

9. The display apparatus of claim 7, wherein the first light-emitting diode, each of the second light-emitting diodes and each of the third light-emitting diodes comprise:
an anode electrode electrically connected to the source electrode or the drain electrode;
a cathode electrode facing the anode electrode; and
an emissive layer disposed between the anode electrode and the cathode electrode.

10. The display apparatus of claim 9, wherein each one of the cathode electrodes is spaced apart from each one of other cathode electrodes in the sensor display area.

11. The display apparatus of claim 9, wherein the cathode electrode in the plurality of second sensor sub-pixels is spaced apart between the second-first sensor sub-pixel and the second-second sensor sub-pixel.

12. The display apparatus of claim 9, further comprising:
an encapsulation layer disposed on the cathode electrode; and
a touch member disposed on the encapsulation layer.

13. The display apparatus of claim 12, wherein the touch member comprises:
a touch insulating layer; and
a touch electrode disposed on the touch insulating layer,
wherein the touch electrode is disposed between the second-first sub-pixel and the second-second sensor sub-pixel.

14. The display apparatus of claim 13, further comprising a light-shielding layer disposed on the encapsulation layer corresponding to the touch electrode.

15. The display apparatus of claim 9, wherein the first sensor sub-pixel comprises a single emissive layer only.

16. The display apparatus of claim 1, wherein the first sensor sub-pixel is directly surrounded by a plurality of sensor transparent areas.

17. The display apparatus of claim 16, wherein the first sensor sub-pixel is directly adjacent to at least four sensor transparent areas.

18. The display apparatus of claim 1, wherein the plurality of second sensor sub-pixels and the plurality of third sensor sub-pixels are directly adjacent to the first sensor sub-pixel.

19. The display apparatus of claim 1, wherein a size of a sensor display area pixel is greater than a size of a display area pixel.

20. The display apparatus of claim 19, wherein one sensor area comprises at least four sensor transparent areas.
